(19) United States
(12) Patent Application Publication
(10) Pub. No.: US 2008/0000680 A1
(43) Pub. Date: Jan. 3, 2008

(54) Printed circuit board and method of manufacturing the same

(75) Inventors: Suk Hyeon Cho, Gyunggi-do (KR); Byoung Youl Min, Gyunggi-do (KR); Je Gwang Yoo, Gyunggi-do (KR); Hae Nam Seo, Seoul (KR); Byung Moon Kim, Gyunggi-do (KR); Ji Hong Jo, Chungcheongnam-do (KR); Han Seo Cho, Daejeon (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 11/819,925

(22) Filed: Jun. 29, 2007

(30) Foreign Application Priority Data
Jun. 30, 2006 (KR) 10-2006-0060803

(51) Int. Cl. H05K 1/03

(52) U.S. Cl. 174/262; 29/830; 29/846; 174/255; 174/264

(57) ABSTRACT

Disclosed herein are a printed circuit board and a method of manufacturing the same, which can achieve reliable heat resistance because heat radiation characteristics are improved, and processing costs of which are reduced because processing times are shortened.

### CROSS REFERENCE TO RELATED APPLICATION

This application claims the benefit of Korean Patent Application No. 10-2006-0060803, filed Jun. 30, 2006, entitled “Printed Circuit Board and Fabricating Method of the Same”, which is hereby incorporated by reference in its entirety into this application.

### BACKGROUND OF THE INVENTION

1. Field of the Invention

The present invention relates to a printed circuit board and a method of manufacturing the same, and, more particularly, to a printed circuit board and a method of manufacturing the same, which can secure reliability for heat resistance by improving heat radiation characteristics, and can reduce processing costs by shortening processing times.

2. Description of the Related Art

As portable electronic goods become miniaturized, space for mounting semiconductors therein is decreasing, and the electronic products are becoming more multi-functional. Accordingly, a semiconductor package must be light, thin, short and small to increase the mounting efficiency of semiconductors per unit volume of space.

As such, in order to allow the package to be light, thin short and small, a method of decreasing the thicknesses of parts and the printed circuit board, or of installing parts normally mounted on the surface of the printed circuit board in the interior of the printed circuit board, rather than on the surface thereof, is required. Thus, various methods of manufacturing a printed circuit board so as to embed chips therein have been researched.

Thus, methods of mounting chips in a printed circuit board, as disclosed in Korean Unexamined Patent Publication No. 2006-5840 and United States Unexamined Patent Publication No. 2005-0255303, have been developed in the form of forming a space in a printed circuit board and then embedding parts into the space.

However, when chips are mounted in a printed circuit board using these technologies, there is a problem in that processing times and processing costs are increased because holes must be additionally formed in an insulating material, and then interconnections are formed through a plating process for inter-layer connection.

Further, these conventional methods of embedding chips in a printed circuit board have a problem in that, when parts having thicknesses different from each other are embedded in a printed circuit board, the precision of the portion connected with each of the parts is decreased.

### SUMMARY OF THE INVENTION

Accordingly, the present invention has been made in order to solve the above problems, and an object of the present invention is to provide a printed circuit board and a method of manufacturing the same, which can reduce processing costs by shortening processing times.

Another object of the present invention is to provide a printed circuit board and a method of manufacturing the same, which can increase the precision of the portion connected with each part embedded in a printed circuit board without regard to the thickness of the parts mounted therein.

A further object of the present invention is to provide a printed circuit board and a method of manufacturing the same, which has an improved heat radiation effect by increasing heat radiation characteristics in horizontal and vertical directions.

A still further object of the present invention is to provide a printed circuit board and a method of manufacturing the same, which can decrease a phenomenon of signal interference between parts by shielding the parts embedded in a printed circuit board.

In order to accomplish the above objects, according to an aspect of the present invention, a printed circuit board includes a first insulation layer; a plurality of interlayer connection members, which are conductors, formed on the first insulation layer; a second insulation layer layered on the first insulation layer to have the same thickness as the connection member; a third insulation layer layered on the second insulation layer; circuit patterns formed on the first insulation layer and the third insulation layer, respectively; and a plurality of blind via holes formed in the first insulation layer and the third insulation layer to electrically connect the circuit patterns with the connection members.

According to another aspect of the present invention, a printed circuit board includes a first insulation layer; a plurality of interlayer connection members, which are conductors, formed on the first insulation layer; a second insulation layer layered on the first insulation layer and having a thickness enough to be capable of filling spaces between the connection members; a third insulation layer layered on the second insulation layer; circuit patterns formed on the first insulation layer and the third insulation layer, respectively; and a plurality of blind via holes formed in the first insulation layer and the third insulation layer to electrically connect the circuit patterns with the connection members.

According to a further aspect of the present invention, a method of manufacturing a printed circuit board includes the steps of (a) providing a copper clad laminate, in which copper foil is layered on first and second surfaces of a first insulation layer; (b) forming a plurality of interlayer connection members, which are conductors, by selectively removing the copper foil layered on the first surface of the first insulation layer; (c) layering a second insulation layer and an RCC, one surface of which is coated with a copper foil, on the first insulation layer; (d) forming blind via holes in an outermost copper foil and the first insulation layer, and another outermost copper foil and the second insulation layer; and (e) forming circuit patterns by patterning the outermost copper foil.

According to a still further aspect of the present invention, a method of manufacturing a printed circuit board includes the steps of (a) providing a copper clad laminate in which copper foil is layered on first and second surfaces of a first insulation layer; (b) forming a plurality of interlayer connection members, which are conductors, by selectively removing the copper foil layered on the first surface of the first insulation layer; (c) layering a second insulation layer on the first insulation layer; (d) layering a third insulation layer and an RCC, one surface of which is coated with copper foil, on the second insulation layer; (e) forming blind via holes in the first insulation layer and the third insulation layer; and (f) forming circuit patterns by patterning the outermost copper foil.

### BRIEF DESCRIPTION OF THE DRAWINGS

FIG. 1 is a sectional view showing a printed circuit board according to a first embodiment of the present invention;

FIG. 2 is a sectional view showing a printed circuit board according to a second embodiment of the present invention;

FIG. 3 is a sectional view showing a printed circuit board according to a third embodiment of the present invention;

FIGS. 4A to 4E are process sectional views showing a method of manufacturing the printed circuit board shown in FIG. 3;

FIG. 5 is a sectional view showing a printed circuit board according to a fourth embodiment of the present invention;

FIG. 6 is a sectional view showing a printed circuit board according to a fifth embodiment of the present invention;

FIG. 7 is a sectional view showing a printed circuit board according to a sixth embodiment of the present invention; and

FIGS. 8A to 8D are process sectional views showing a method of manufacturing the printed circuit board shown in FIG. 7.

### DESCRIPTION OF THE PREFERRED EMBODIMENTS

Hereinafter, preferred embodiments of the present invention will be described in detail with reference to the attached drawings.

Reference now should be made to the drawings, in which the same reference numerals are used throughout the different drawings to designate the same or similar components.

FIG. 1 is a sectional view showing a printed circuit board according to a first embodiment of the present invention.

Referring to FIG. 1, a printed circuit board according to a first embodiment of the present invention includes a substrate 10 including a first insulation layer 2, a first circuit pattern 4a layered on the lower portion of the first insulation layer 2, and a plurality of interlayer connection members 6a and heat radiation layers 6 formed on the upper portion of the first insulation layer 2; a second insulation layer 12 layered on the first insulation layer 2; a third insulation layer 14 layered on the upper portions of the second insulation layer 12, the connection members 6a and the heat radiation layers 6; and a second circuit pattern 4b formed on the third insulation layer 14. In this case, the same materials or different materials are used as the first insulation layer 2, the second insulation layer 12 and the third insulation layer 14.

In the printed circuit board according to a first embodiment of the present invention, a plurality of blind via holes 16 is formed in the first insulation layer 2 and the third insulation layer 14 to electrically connect the plurality of connection members 6a and the heat radiation layers 6 to the first circuit pattern 4a and the second circuit pattern 4b.

The substrate 10 includes a first insulation layer 2, a first circuit pattern 4a formed on the lower portion of the first insulation layer 2, and connection members 6a and heat radiation layers 6 formed on the upper portion of the first insulation layer 2.

The connection members 6a are formed on the upper portion of the first insulation layer 2, that is, in the inner portion of the second insulation layer 12, and are thus used as inner via holes for the interlayer connection of the second insulation layer 12, that is, for the electrical connection of the upper portion and lower portion thereof. Each of the connection members 6a is thicker than a first copper foil 4a and is formed in the general shape of a cylinder, thereby serving to discharge heat generated in the printed circuit board in a vertical direction. In this case, each of the connection members 6a may be formed in the shape of a polygon such as a triangle or a rectangle, rather than in the shape of a cylinder.

The heat radiation layers 6 are formed on the upper portion of the first insulation layer 2, that is, in the inner portion of the second insulation layer 12, so as to be thicker than the first copper foil 4a, and thus serve to discharge heat generated in the printed circuit board in a vertical or horizontal direction. In order to discharge the heat, the heat radiation layers 6 are electrically connected to the first circuit pattern 4a and the second circuit pattern 4b through the blind via holes 16.

These heat radiation layers 6 are formed between the interlayer connection member 6a so that widths of upper surface and lower surfaces thereof are greater than those of the upper surface and lower surface of the connection member 6a.

In this case, the connection member 6a and the heat radiation layers 6 have greater thicknesses than the first insulation layer 2 and the third insulation layer 14.

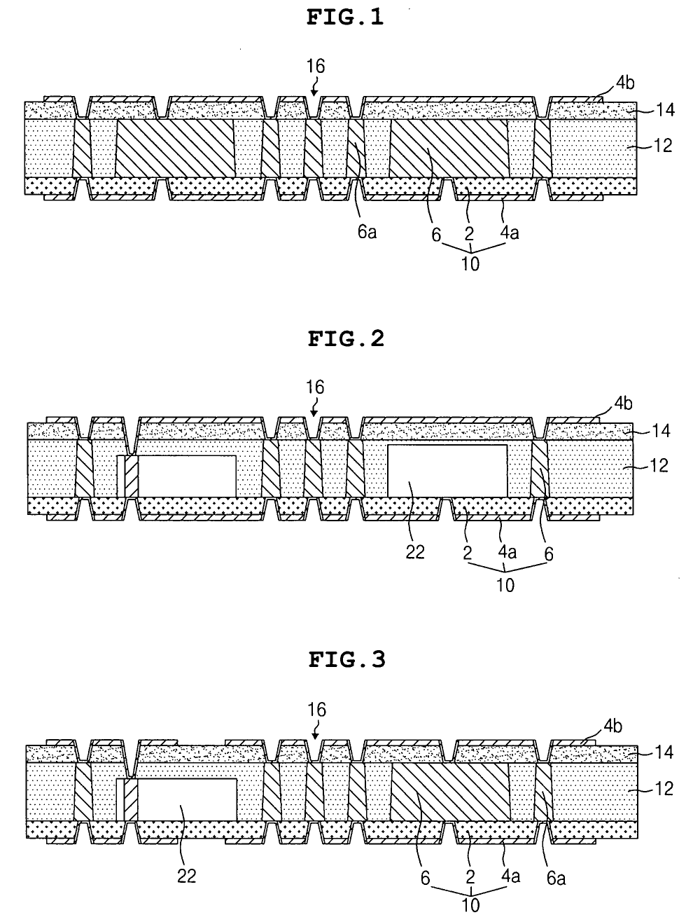

FIG. 2 is a sectional view showing a printed circuit board according to a second embodiment of the present invention.

Here, the same reference numerals are used in the second embodiment of the present invention to designate components the same as, or similar to, those of the first embodiment of the present invention.

Referring to FIG. 2, a printed circuit board according to a second embodiment of the present invention includes a substrate 10 including a first insulation layer 2, a first circuit pattern 4a layered on the lower portion of the first insulation layer 2, and a plurality of interlayer connection members 6a formed on the upper portion of the first insulation layer 2; a second insulation layer 12 layered on the first insulation layer 2; a third insulation layer 14 layered on the upper portions of the second insulation layer 12 and the connection members 6a; and a second circuit pattern 4b formed on the third insulation layer 14. Here, the same materials or different materials are used as the first insulation layer 2, the second insulation layer 12 and the third insulation layer 14.

In the printed circuit board according to a second embodiment of the present invention, a plurality of blind via holes 16 is formed in the first insulation layer 2 and the third insulation layer 14 to electrically connect the plurality of connection members 6a and the parts 22 to the first circuit pattern 4a and the second circuit pattern 4b.

The substrate 10 includes a first insulation layer 2, a first circuit pattern 4a formed on the lower portion of the first insulation layer 2, and connection members 6a formed on the upper portion of the first insulation layer 2.

The connection members 6a are formed on the upper portion of the first insulation layer 2, that is, in the inner portion of the second insulation layer 12, and are thus used as inner via holes for the interlayer connection of the second insulation layer 12, that is, for the electrical connection of the upper portion and lower portion thereof.

Further, the connection members 6a serve as a shielding film for blocking a signal interference phenomenon between the parts embedded in the printed circuit board.

These connection members 6a have thicknesses the same as or greater than those of the parts 22 embedded in the printed circuit board and are formed in the general shape of a cylinder, thereby serving to discharge heat generated in the printed circuit board in a vertical direction. In this case, the connection members 6a, enclosing the parts 22 embedded in the printed circuit board, may be formed in the shape of a polygon, such as a triangle or a rectangle, rather than in the shape of cylinder.

The parts 22 are any one, or two or more, of a bare IC chip, a passive part, a part having a module packed therein, and a module substrate having various components packed therein.

In this case, the parts 22 have the same or different thicknesses from each other when different kinds of parts are embedded in the printed circuit board.

These parts 22 are mounted between the interlayer connection members 6a.

FIG. 3 is a sectional view showing a printed circuit board according to a third embodiment of the present invention.

Here, the same reference numerals are used in the third embodiment of the present invention to designate components that are the same as or similar to those of the first embodiment of the present invention.

Referring to FIG. 3, a printed circuit board according to a third embodiment of the present invention includes a substrate 10 including a first insulation layer 2, a first circuit pattern 4a layered on the lower portion of the first insulation layer 2, and a plurality of interlayer connection members 6a and heat radiation layers 6 formed on the upper portion of the first insulation layer 2; a second insulation layer 12 layered on the first insulation layer 2; parts 22 mounted in the second insulation layer 12; a third insulation layer 14 layered on the upper portions of the second insulation layer 12, the connection members 6a and the heat radiation layers 6; and a second circuit pattern 4b formed on the third insulation layer 14. Here, the same materials or different materials are used as the first insulation layer 2, the second insulation layer 12 and the third insulation layer 14.

In the printed circuit board according to a third embodiment of the present invention, a plurality of blind via holes 16 is formed in the first insulation layer 2 and the third insulation layer 14 to electrically connect the plurality of connection members 6a, the heat radiation layers 6 and the parts 22 to the first circuit pattern 4a and the second circuit pattern 4b.

The substrate 10 includes a first insulation layer 2, a first circuit pattern 4a formed on the lower portion of the first insulation layer 2, and connection members 6a and a heat radiation layer 6 formed on the upper portion of the first insulation layer 2.

The connection members 6a are formed on the upper portion of the first insulation layer 2, that is, in the inner portion of the second insulation layer 12, and are thus used as inner via holes for the interlayer connection of the second insulation layer 12, that is, for the electrical connection of the upper portion and lower portion thereof.

These connection members 6a are formed in the general shape of a cylinder, thereby serving to discharge heat generated in the printed circuit board in a vertical direction. In this case, the connection members 6a may be formed in the shape of a polygon, such as a triangle or a rectangle, rather than in the shape of cylinder.

The heat radiation layers 6 are formed on the upper portion of the first insulation layer 2, that is, in the inner portion of the second insulation layer 12, and thus serve to discharge heat generated in the printed circuit board in a vertical or horizontal direction. In order to discharge the heat, the heat radiation layers 6 are electrically connected to the first circuit pattern 4a and the second circuit pattern 4b through the blind via holes 16.

These heat radiation layers 6 are formed between the interlayer connection members 6a such that widths of upper and lower surfaces thereof are greater than those of the upper surface and lower surface of the connection member 6a.

Here, the connection members 6a serve as a shielding film for blocking a signal interference phenomenon between the parts embedded in the printed circuit board.

These connection members 6a and heat radiation layers 6 have thicknesses the same as or greater than those of the parts 22 embedded in the printed circuit board.

The parts 22 are any one, or two or more, of a bare IC chip, a passive part, a part having a module packed therein, and a module substrate having various components packed therein.

In this case, the parts 22 have the same or different thicknesses from each other when different kinds of parts are embedded in the printed circuit board.

These parts 22 are mounted between the interlayer connection members 6a.

As described above, in the printed circuit board according to the embodiment of the present invention, the heat radiation effect in a vertical direction can be improved because the connection members 6a formed of cylindrical conductors are used as inner via holes.

Further, in the printed circuit board according to the embodiment of the present invention, the heat radiation effect in vertical and horizontal directions can be improved because heat radiation layers 6 having large areas are formed in the printed circuit board.

Further, in the printed circuit board according to the embodiment of the present invention, a signal interference phenomenon between the parts embedded in the printed circuit board can be reduced because the connection members 6a and heat radiation layers 6 shield the parts mounted in the printed circuit board.

Further, in the printed circuit board according to the embodiment of the present invention, the shielding effect can be improved because a signal interference effect in the printed circuit board is reduced by connecting the connection members 6a and heat radiation layers 6 to the external ground through the blind via holes 16 formed in the lower portion of the first insulation layer 2 when the parts are mounted in the printed circuit board.

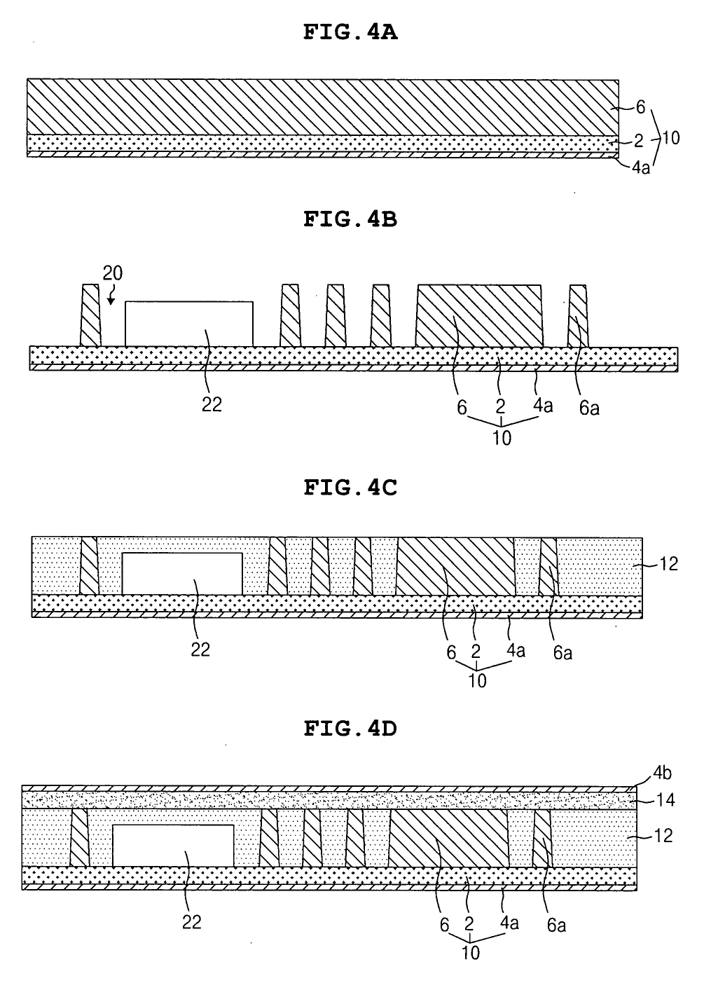

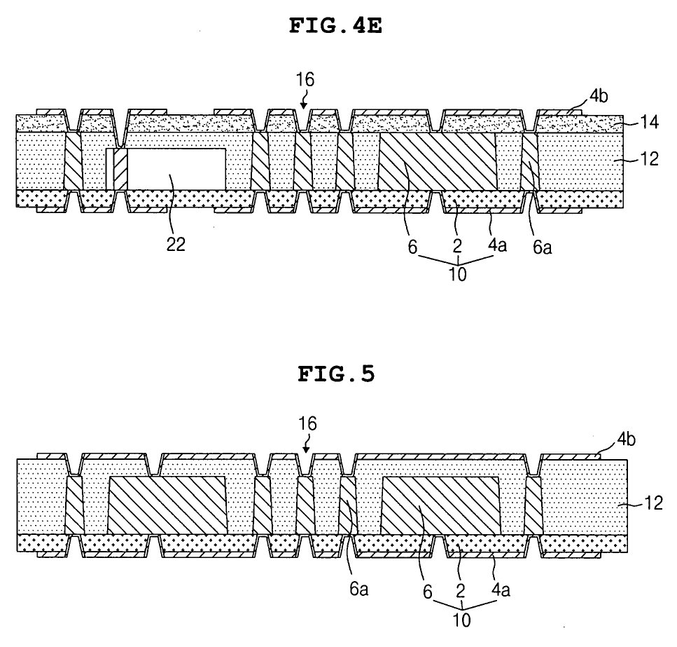

FIGS. 4A to 4E are process sectional views showing the method of manufacturing the printed circuit board shown in FIG. 3.

First, as shown in FIG. 4A, a substrate 10, which is a copper clad laminate in which a first copper foil 4a and a second copper foil 6, each of which has a different thickness, are attached on a first surface and a second surface of a first insulation layer 2, is provided. In this case, the second copper foil 6, as shown in FIGS. 2 and 3, is as thick as or thicker than parts to be embedded in the printed circuit board when the parts are embedded therein, and the second copper foil 6, as shown in FIG. 1, is thicker than the first copper foil 4a when the parts are not embedded therein.

Next, as shown in FIG. 4B, connection members 6a, heat radiation layers 6 and/or part mounting regions 20 are formed by selectively removing the second copper foil 6 using an etching solution. In this case, the connection members 6a are used as inner via holes. Further, the heat radiation layers 6 and/or the part mounting regions 20 are formed between the interlayer connection members 6a.

When the second copper foil 6 is selectively removed at the time of the etching process thereof, the connection members 6a are necessarily formed, but any one of the heat radiation layers 6 and the part mounting regions 20 need not be formed.

That is, the part mounting regions 20, as shown in FIG. 1, need not be formed when the parts are not embedded in the printed circuit board, and the heat radiation layers 6, as shown in FIG. 2, need not be formed when a plurality of parts 22 is embedded in the printed circuit board.

However, when the parts 22 are embedded in the printed circuit board, it is preferred that both the part mounting regions 20 and the heat radiation layers 6, as shown in FIG. 3, be formed.

When only the connection members 6a and the heat radiation layers 6, as shown in FIG. 1, are formed by selectively removing the second copper foil 6, a second insulation layer 12 is placed on a first insulation layer 2, and then the second insulation layer 12 is layered on the first insulation layer 2 by applying heat and pressure thereto using a press. In this case, the second insulation layer 12 is formed to have the same thickness as the connection members 6a and the heat radiation layers 6. Further, the heat radiation layers 6 are formed between the interlayer connection members 6a such that widths of the upper surface and lower surface thereof are greater than those of the upper surface and lower surface of the connection members 6a.

However, when only the connection members 6a and the part mounting regions 20, as shown in FIG. 2, are formed by selectively removing the second copper foil 6, parts 22 are mounted in the part mounting regions 20, and then a second insulation layer 12 is placed on a first insulation layer 2, and then the second insulation layer 12 is layered on the first insulation layer 2 by applying heat and pressure thereto using a press. In this case, the second insulation layer 12 is formed to have the same thickness as the connection members 6a.

Further, when the connection members 6a, the heat radiation layers 6 and the part mounting regions 20, as shown in FIG. 3, are formed by selectively removing the second copper foil 6, a part 22 is mounted in the part mounting regions 20, a second insulation layer 12 is placed on a first insulation layer 2, and then the second insulation layer 12 is layered on the first insulation layer 2 by applying heat and pressure thereto using a press. In this case, the second insulation layer 12 is formed to have the same thickness as the connection members 6a and the heat radiation layers 6. Further, the heat radiation layers 6 are formed such that widths of the upper surface and lower surface thereof are greater than those of the upper surface and lower surface of the connection members 6a.

After the second insulation layer 12 is deposited on the first insulation layer 2, if residue from the second insulation layer 12 consequently remains on the connection members 6a and the heat radiation layers 6, the upper portion of the substrate, that is, the upper portions of the second insulation layer 12, the connection members 6a and the heat radiation layers 6, is abraded using an abrader. Accordingly, the residue from the second insulation layer 12 remaining on the upper portions of the connection members 6a and the heat radiation layers 6 is removed.

Then, as shown in FIG. 4D, a Resin Coated Copper foil (RCC), including a third insulation layer 14 and a third copper foil 4b, is deposited on the second insulation layer 2 by applying heat and pressure thereto using a press. Here, the third insulation layer 14 may be deposited on the second insulation layer 12, and then the third copper foil 4b may be deposited on the second insulation layer 12.

After the third copper foil 4b is deposited on the second insulation layer 12, blind via holes 16 are formed using a laser to connect the first copper foil 4a and the third copper foil 4b with the connection members 6a and the heat radiation layers 6.

After the blind via holes 16 are formed, as shown in FIG. 4E, conductivity is imparted to the blind via holes 16 through an electroless plating process, and then circuit patterns 4a and 4b are formed through an image forming process.

As described above, in the method of manufacturing a printed circuit board according to the embodiment of the present invention, various parts having different sizes and thicknesses, such as a bare IC chip, a passive part, a part having a module packed therein, and a module substrate having various components packed therein, can be embedded in the printed circuit board, and the precision connection with each of the parts can be also increased, because the second copper foil 6, which is as thick as or thicker than each of the parts embedded in the printed circuit board, is selectively removed, the parts are mounted in the portions from which the second copper foil 6 was removed, the second insulation layer 12 is deposited on the parts, and then the via holes are formed, and thus the terminals of the parts are connected to the circuit patterns through the via holes.

Further, in the method of manufacturing a printed circuit board according to the embodiment of the present invention, the connection members 6a formed by selectively removing the second copper foil 6 are used as inner via holes, so that an electroless plating process and an electrolytic plating process, which are performed to provide conductivity for the inner via holes, which pass through the second insulation layer 12, need not be performed, thereby decreasing processing times and processing costs.

Further, in the method of manufacturing a printed circuit board according to the embodiment of the present invention, the connection members 6a, which are cylindrical conductors, are used as inner via holes, so that heat radiation effect in a vertical direction can be improved. Further, the heat radiation layers having large widths are formed in a substrate, so that heat in the substrate is discharged in both vertical and horizontal directions, thereby increasing the heat radiation effect.

Further, in the method of manufacturing a printed circuit board according to the embodiment of the present invention, a signal interference phenomenon between the parts embedded in the printed circuit board can be reduced, because the parts embedded therein are shielded by the connection members 6a and the heat radiation layers 6.

FIG. 5 is a sectional view showing a printed circuit board according to a fourth embodiment of the present invention.

Here, the same reference numerals are used in the fourth embodiment of the present invention to designate components the same as, or similar to, those of the first embodiment of the present invention.

Referring to FIG. 5, a printed circuit board according to a fourth embodiment of the present invention includes a substrate 10 including a first insulation layer 2, a first circuit pattern 4a layered on the lower portion of the first insulation layer 2, and a plurality of interlayer connection members 6a and heat radiation layers 6 formed on the upper portion of the first insulation layer 2; a second insulation layer 12 layered on the first insulation layer 2, the connection members 6a and the heat radiation layers 6; and a second circuit pattern 4b formed on the second insulation layer 12. In this case, the same materials or different materials are used as the first insulation layer 2 and the second insulation layer 12.

In the printed circuit board according to a fourth embodiment of the present invention, a plurality of blind via holes 16 is formed in the first insulation layer 2 and the second insulation layer 12 to electrically connect the plurality of connection members 6a and the heat radiation layers 6 to the first circuit pattern 4a and the second circuit pattern 4b.

The substrate 10 includes a first insulation layer 2, a first circuit pattern 4a formed on the lower portion of the first insulation layer 2, and connection members 6a and heat radiation layers 6 formed on the upper portion of the first insulation layer 2.

The connection members 6a are formed on the upper portion of the first insulation layer 2, that is, in the inner portion of the second insulation layer 12, and are thus used as inner via holes for the interlayer connection of the second insulation layer 12, that is, for the electrical connection of the upper portion and lower portion thereof. Each of the connection members 6a is thicker than a first copper foil 4a and is formed in the general shape of a cylinder, thereby serving to discharge heat generated in the printed circuit board in a vertical direction. In this case, each of the connection members 6a may be formed in the shape of a polygon, such as a triangle or a rectangle, rather than in the shape of a cylinder.

The heat radiation layers 6 are formed on the upper portion of the first insulation layer 2, that is, in the inner portion of the second insulation layer 12, to be thicker than the first copper foil 4a, and thus serves to discharge heat generated in the printed circuit board in a vertical or horizontal direction.

These heat radiation layers 6 are formed between the interlayer connection members 6a such that widths of the upper surface and lower surface thereof are greater than those of the upper surface and lower surface of the connection member 6a.

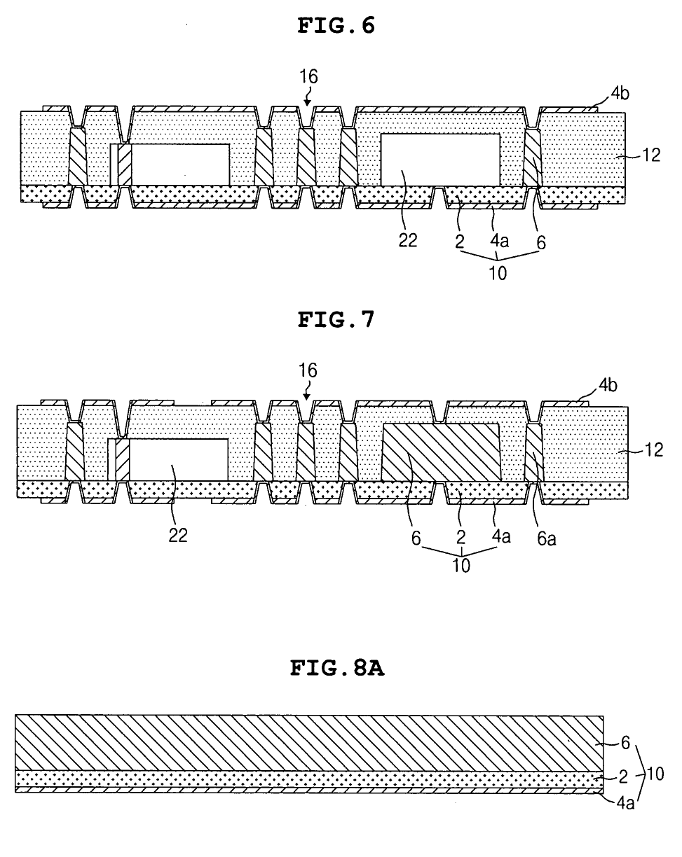

FIG. 6 is a sectional view showing a printed circuit board according to a fifth embodiment of the present invention.

Here, the same reference numerals are used in the fifth embodiment of the present invention to designate components that are the same as, or similar to, those of the first embodiment of the present invention.

Referring to FIG. 6, a printed circuit board according to a fifth embodiment of the present invention includes a substrate 10 including a first insulation layer 2, a first circuit pattern 4a layered on the lower portion of the first insulation layer 2, and a plurality of interlayer connection members 6a formed on the upper portion of the first insulation layer 2; a second insulation layer 12 layered on the first insulation layer 2 and the connection members 6a; parts 22 mounted in the second insulation layer 12; and a second circuit pattern 4b formed on the second insulation layer 12. Here, the same materials or different materials are used as the first insulation layer 2 and the second insulation layer 12.

In the printed circuit board according to a fifth embodiment of the present invention, a plurality of blind via holes 16 is formed in the first insulation layer 2 and the second insulation layer 12 to electrically connect the plurality of connection members 6a and the parts 22 to the first circuit pattern 4a and the second circuit pattern 4b.

The substrate 10 includes a first insulation layer 2, a first circuit pattern 4a formed on the lower portion of the first insulation layer 2, and connection members 6a formed on the upper portion of the first insulation layer 2.

The connection members 6a are formed on the upper portion of the first insulation layer 2, that is, in the inner portion of the second insulation layer 12, and are thus used as inner via holes for the interlayer connection of the second insulation layer 12, that is, for the electrical connection between the upper portion and lower portion thereof.

Further, the connection members 6a serve as a shielding film for blocking a signal interference phenomenon between the parts embedded in the printed circuit board.

These connection members 6a are as thick as or thicker than the parts 22 embedded in the printed circuit board and are formed in the general shape of a cylinder, thereby serving to discharge heat generated in the printed circuit board in a vertical direction. In this case, the connection members 6a, enclosing the parts 22 embedded in the printed circuit board, may be formed in the shape of a polygon, such as a triangle or a rectangle, rather than in the shape of cylinder.

The parts 22 are any one, or two or more, of a bare IC chip, a passive part, a part having a module packed therein, and a module substrate having various components packed therein.

In this case, the parts 22 have the same or different thicknesses from each other when different kinds of parts are embedded in the printed circuit board.

These parts 22 are mounted between the interlayer connection members 6a.

FIG. 7 is a sectional view showing a printed circuit board according to a sixth embodiment of the present invention.

Here, the same reference numerals are used in the sixth embodiment of the present invention to designate components the same as, or similar to, those of the first embodiment of the present invention.

Referring to FIG. 7, a printed circuit board according to a sixth embodiment of the present invention includes a substrate 10 including a first insulation layer 2, a first circuit pattern 4a layered on the lower portion of the first insulation layer 2, and a plurality of interlayer connection members 6a and heat radiation layers 6 formed on the upper portion of the first insulation layer 2; a second insulation layer 12 layered on the first insulation layer 2, the connection members 6a and the heat radiation layers 6; parts 22 mounted in the second insulation layer 12; and a second circuit pattern 4b formed on the second insulation layer 12. In this case, the same materials or different materials are used as the first insulation layer 2 and the second insulation layer 12.

In the printed circuit board according to a sixth embodiment of the present invention, a plurality of blind via holes 16 is formed in the first insulation layer 2 and the second insulation layer 12 to electrically connect the plurality of connection members 6a, the heat radiation layers 6 and the parts 22 to the first circuit pattern 4a and the second circuit pattern 4b.

The substrate 10 includes a first insulation layer 2, a first circuit pattern 4a formed on the lower portion of the first insulation layer 2, and connection members 6a and a heat radiation layer 6 formed on the upper portion of the first insulation layer 2.

The connection members 6a are formed on the upper portion of the first insulation layer 2, that is, in the inner portion of the second insulation layer 12, and are thus used as inner via holes for the interlayer connection of the second insulation layer 12, that is, for the electrical connection of the upper portion and lower portion thereof.

These connection members 6a are formed in the general shape of a cylinder, thereby serving to discharge heat generated in the printed circuit board in a vertical direction. In this case, the connection members 6a may be formed in the shape of a polygon, such as a triangle or a rectangle, rather than in the shape of cylinder.

The heat radiation layers 6 are formed on the upper portion of the first insulation layer 2, that is, in the inner portion of the second insulation layer 12, and thus serve to discharge heat generated in the printed circuit board in a vertical or horizontal direction.

These heat radiation layers 6 are formed between the interlayer connection members 6a such that widths of the upper surface and lower surface thereof are greater than those of the upper surface and lower surface of the connection member 6a.

Here, the connection members 6a and the heat radiation layers 6 serve as a shielding film for blocking a signal interference phenomenon between the parts embedded in the printed circuit board.

These connection members 6a and heat radiation layers 6 are as thick as or thicker than the parts 22 embedded in the printed circuit board.

The parts 22 are any one, or two or more, of a bare IC chip, a passive part, a part having a module packed therein, and a module substrate having various components packed therein.

In this case, the thicknesses of the parts 22 are the same as or different from each other when different kinds of parts are embedded in the printed circuit board.

These parts 22 are mounted between the interlayer connection members 6a.

As described above, in the printed circuit board according to the embodiment of the present invention, a heat radiation effect in a vertical direction can be improved because the connection members 6a formed of cylindrical conductors are used as inner via holes.

Further, in the printed circuit board according to the embodiment of the present invention, a heat radiation effect in vertical and horizontal directions can be improved because heat radiation layers 6 having large areas are in the printed circuit board.

Further, in the printed circuit board according to the embodiment of the present invention, the signal interference phenomenon between the parts embedded in the printed circuit board can be reduced because the connection members 6a and heat radiation layers 6 shield the parts embedded in the printed circuit board.

Further, in the printed circuit board according to the embodiment of the present invention, the shielding effect can be improved because the signal interference effect in the printed circuit board is reduced by connecting the connection members 6a and heat radiation layers 6 to the external ground through the blind via holes 16 formed on the lower portion of the first insulation layer 2 when the parts are embedded in the printed circuit board.

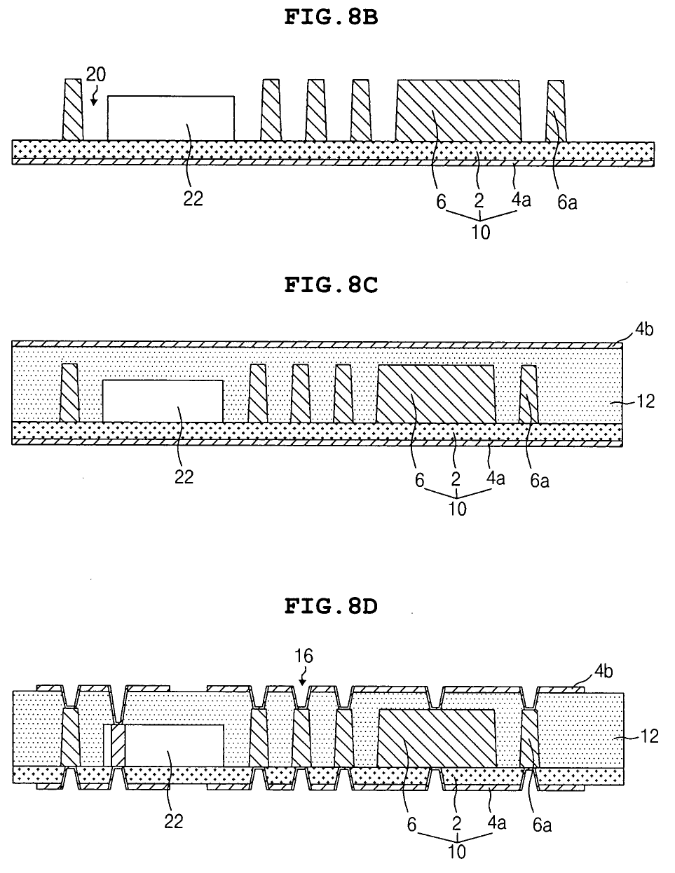

FIGS. 8A to 8D are process sectional views showing a method of manufacturing the printed circuit board shown in FIG. 7.

First, as shown in FIG. 8A, a substrate 10, which is a copper clad laminate in which a first copper foil 4a and a second copper foil 6, each of which has a different thickness, are attached on a first surface and a second surface of a first insulation layer 2, is provided. In this case, the second copper foil 6, as shown in FIGS. 6 and 7, is as thick as or thicker than parts to be embedded in the printed circuit board when the parts are mounted therein, and the second copper foil 6, as shown in FIG. 5, is thicker than the first copper foil 4a when no parts are embedded therein.

Next, as shown in FIG. 8B, connection members 6a, heat radiation layers 6 and part mounting regions 20 are formed by selectively removing the second copper foil 6 using an etching solution. In this case, the connection members 6a are used as inner via holes.

When the second copper foil 6 is selectively removed at the time of the etching process thereof, the connection members 6a are necessarily formed, but any one of the heat radiation layers 6 and the part mounting regions 20 need not be formed.

That is, the part mounting regions 20, as shown in FIG. 5, need not be formed when no parts are embedded in the printed circuit board, and the heat radiation layers 6, as shown in FIG. 6, need not be formed when a plurality of parts 22 is embedded in the printed circuit board.

However, when the parts 22 are embedded in the printed circuit board, it is preferred that both the part mounting regions 20 and the heat radiation layers 6, as shown in FIG. 7, be formed.

When only the connection members 6a and the heat radiation layers 6, as shown in FIG. 5, are formed by selectively removing the second copper foil 6, an RCC including a second insulation layer 12 and a third copper foil 4b is placed on the connection members 6a and the heat radiation layers 6, and then is layered thereon by applying heat and pressure thereto using a press.

In this case, the second insulation layer 12 and the third copper foil 4b may be separately layered.

That is, the second insulation layer 12 may be layered on the connection members 6a and the heat radiation layers 6, and then the third copper foil 4b may be layered on the second insulation layer 12.

In this case, the second insulation layer 12 is formed to be thicker than the connection members 6a and the heat radiation layers 6. Further, the heat radiation layers 6 are formed such that widths of the upper surfaces and lower surfaces thereof are greater than those of the upper surfaces and lower surfaces of the connection members 6a.

However, when only the connection members 6a and the part mounting regions 20, as shown in FIG. 6, are formed by selectively removing the second copper foil 6, parts 22 are mounted in the part mounting regions 20, and then an RCC including a second insulation layer 12 and a third copper foil 4b is placed on the connection members 6a and the heat radiation layers 6 and then is layered thereon by applying heat and pressure thereto using a press.

In this case, the second insulation layer 12 and the third copper foil 4b may be separately layered.

That is, the second insulation layer 12 may be layered on the connection members 6a and the heat radiation layers 6, and then the third copper foil 4b may be layered on the second insulation layer 12.

In this case, the second insulation layer 12 is formed to a thickness such that it is capable of filling spaces between the connection members 6a and the heat radiation layers 6. Further, the heat radiation layers 6 are formed such that widths of the upper surface and lower surface thereof are greater than those of the upper surface and lower surface of the connection members 6a.

Further, when the connection members 6a, the heat radiation layers 6 and the part mounting regions 20, as shown in FIG. 7, are formed by selectively removing the second copper foil 6, as shown in FIG. 8C, an RCC including a second insulation layer 12 and a third copper foil 4b, is placed on the connection members 6a, the heat radiation layers 6 and the parts, and then is layered thereon by applying heat and pressure thereto using a press.

In this case, the second insulation layer 12 and the third copper foil 4b may be separately layered.

That is, the second insulation layer 12 may be layered on the connection members 6a and the heat radiation layers 6, and then the third copper foil 4b may be layered on the second insulation layer 12.

In this case, the second insulation layer 12 is formed to a thickness such that it is capable of filling spaces between the connection members 6a and the heat radiation layers 6. Further, the heat radiation layers 6 are formed such that widths of the upper surface and lower surface thereof are greater than those of the upper surface and lower surface of the connection members 6a.

After the third copper foil 4b is deposited on the second insulation layer 12, as shown in FIG. 8D, blind via holes 16 are formed using a laser to connect the first copper foil 4a and the third copper foil 4b with the connection members 6a and the heat radiation layers 6, and then a copper plating layer is formed in the blind via holes 16.

Then, circuit patterns 4a and 4b are formed through an image forming process.

As described above, in the method of manufacturing a printed circuit board according to the embodiment of the present invention, various parts having different sizes and thicknesses, such as a bare IC chip, a passive part, a part having a module packed therein, and a module substrate having various components packed therein, can be embedded in the printed circuit board, and the precision of the portion connected with each of the parts can be also increased, because the second copper foil 6 which is as thick as or thicker than each of the parts embedded in the printed circuit board, is selectively removed, the parts are mounted in the portions from which the second copper foil 6 was removed, the second insulation layer 12 is deposited on the parts, and then the via holes are formed, and thus terminals of the parts are connected to the circuit patterns through the via holes.

Further, in the method of manufacturing a printed circuit board according to the embodiment of the present invention, the connection members 6a formed by selectively removing the second copper foil 6 are used as inner via holes, so that an electroless plating process and an electrolytic plating process, which are performed to provide conductivity for the inner via holes passing through the second insulation layer 12, are not performed, thereby decreasing processing times and processing costs.

Further, in the method of manufacturing a printed circuit board according to the embodiment of the present invention, the connection members 6a, which are cylindrical conductors, are used as inner via holes, so that a heat radiation effect in a vertical direction can be improved. Further, the heat radiation layers having large widths are formed in a substrate, so that the heat in the substrate is discharged in vertical and horizontal directions, thereby increasing the heat radiation effect.

Further, in the method of manufacturing a printed circuit board according to the embodiment of the present invention, a signal interference phenomenon between the parts embedded in the printed circuit board can be reduced, because the parts mounted therein are shielded by the connection members 6a and the heat radiation layers 6.

AS described above, in the present invention, processing times and processing costs can be reduced, because connection members that use inner via holes are formed by selectively removing a copper foil, and thus the process of forming the inner via holes is not performed.

Further, in the present invention, various parts having different sizes and thickness, such as a bare IC chip, a passive part, a part having a module packed therein, and a module substrate having various components packed therein, can be embedded in a printed circuit board, and the precision of the connection with each of the parts can be also increased, because the parts are mounted in the portions from which the copper foil was removed, an insulation layer is deposited on the parts, and then via holes are formed, and thus terminals of the parts are connected to circuit patterns.

Further, in the present invention, inner via holes are formed of cylindrical conductors, so that the heat radiation effect in a vertical direction can be improved. Further, heat radiation layers having large areas are formed in a printed circuit board, so that the heat radiation effect in vertical and horizontal directions can be improved, thereby securing reliability for heat resistance.

Further, in the present invention, a signal interference phenomenon between parts embedded in a printed circuit board can be reduced, because the parts embedded therein are shielded by connection members and heat radiation layers.

As described above, although the present invention has been disclosed for illustrative purposes with reference to the preferred embodiments, those skilled in the art will appreciate that various modifications, additions and substitutions are possible, without departing from the scope and spirit of the invention as disclosed in the accompanying claims.

What is claimed is:

1. A printed circuit board, comprising:
a first insulation layer;
a plurality of interlayer connection members, which are conductors, formed on the first insulation layer;
a second insulation layer layered on the first insulation layer to have the same thickness as the connection member;
a third insulation layer layered on the second insulation layer;
circuit patterns formed on the first insulation layer and the third insulation layer, respectively; and
a plurality of blind via holes formed in the first insulation layer and the third insulation layer to electrically connect the circuit patterns with the connection members.

2. The printed circuit board as set forth in claim 1, wherein the connection members are formed in any one shape of a cylinder, a triangle and a rectangle.

3. The printed circuit board as set forth in claim 1, further comprising:
heat radiation layers formed between the connection members located on the first insulation layer.

4. The printed circuit board as set forth in claim 3, wherein each of the heat radiation layers has an upper surface and a lower surface, widths of which are greater than those of an upper surface and a lower surface of each of the connection member.

5. The printed circuit board as set forth in claim 4, wherein the heat radiation layers are electrically connected to the circuit patterns through the blind via holes.

6. The printed circuit board as set forth in claim 5, wherein each of the connection members and each of the heat radiation layers have larger thicknesses than the first insulation layer and the third insulation layer.

7. The printed circuit board as set forth in claim 5, further comprising:
parts embedded in the second insulation layer, in which the heat radiation layers are not formed between the connection members.

8. The printed circuit board as set forth in claim 7, wherein the parts are electrically connected to the circuit patterns through the blind via holes.

9. The printed circuit board as set forth in claim 8, wherein the parts are any one, or two or more, of a bare IC chip, a passive part, a part having a module packed therein, and a module substrate having various components packed therein.

10. The printed circuit board as set forth in claim 9, wherein each of the connection members and each of the heat radiation layers have thicknesses the same as or greater than the parts.

11. The printed circuit board as set forth in claim 1, further comprising:
parts embedded between the connection members located in the second insulation layer.

12. The printed circuit board as set forth in claim 11, wherein the parts are electrically connected to the circuit patterns through the blind via holes.

13. The printed circuit board as set forth in claim 12, wherein the parts are any one, or two or more, of a bare IC chip, a passive part, a part having a module packed therein, and a module substrate having various components packed therein.

14. The printed circuit board as set forth in claim 13, wherein the connection members have thicknesses the same as or greater than the parts.

15. The printed circuit board as set forth in claim 11, wherein the connection members, enclosing the parts, are formed in any one shape of a cylinder, a triangle and a rectangle.

16. The printed circuit board as set forth in claim 15, wherein the connection members are electrically connected to copper foil on the insulation layers through via holes, and thus constitute a shielding film enclosing the upper and lower portions of the parts, thereby serving to block a signal interference phenomenon between the parts.

17. The printed circuit board as set forth in claim 16, wherein the connection members and a portion of the shielding film enclosing the upper and lower portions of the parts are connected to a ground circuit.

18. A printed circuit board, comprising:
a first insulation layer;
a plurality of interlayer connection members, which are conductors, formed on the first insulation layer;
a second insulation layer layered on the first insulation layer to have a thickness enough to be capable of filling spaces between the connection members;
circuit patterns formed on the first insulation layer and the third insulation layer, respectively; and
a plurality of blind via holes formed in the first insulation layer and the third insulation layer to electrically connect the circuit patterns with the connection members.

19. The printed circuit board as set forth in claim 18, wherein the connection members are formed in any one shape of a cylinder, a triangle and a rectangle.

20. The printed circuit board as set forth in claim 19, further comprising:
heat radiation layers formed between the connection members located on the first insulation layer.

21. The printed circuit board as set forth in claim 20, wherein each of the heat radiation layers has an upper surface and a lower surface, widths of which are greater than those of an upper surface and a lower surface of each of the connection member.

22. The printed circuit board as set forth in claim 21, wherein the heat radiation layers are electrically connected to the circuit patterns through the blind via holes.

23. The printed circuit board as set forth in claim 22, wherein each of the connection members and each of the heat radiation layers are thicker than the first insulation layer.

24. The printed circuit board as set forth in claim 22, further comprising:
parts embedded in the second insulation layer, in which the heat radiation layers are not formed between the connection members.

25. The printed circuit board as set forth in claim 23, wherein the parts are electrically connected to the circuit patterns through the blind via holes.

26. The printed circuit board as set forth in claim 25, wherein the parts are any one, or two or more, of a bare IC chip, a passive part, a part having a module packed therein, and a module substrate having various components packed therein.

27. The printed circuit board as set forth in claim 26, wherein each of the connection members and each of the heat radiation layers have thicknesses the same as or greater than the parts.

28. The printed circuit board as set forth in claim 19, further comprising:
parts embedded between the connection members located in the second insulation layer.

29. The printed circuit board as set forth in claim 28, wherein the parts are electrically connected to the circuit patterns through the blind via holes.

30. The printed circuit board as set forth in claim 29, wherein the parts are any one, or two or more, selected from among a bare IC chip, a passive part, a part having a module packed therein, and a module substrate having various components packed therein.

31. The printed circuit board as set forth in claim 30, wherein the connection members have thicknesses the same as or greater than the parts.

32. The printed circuit board as set forth in claim 28, wherein the connection members, enclosing the parts, are formed in any one shape of a cylinder, a triangle and a rectangle.

33. The printed circuit board as set forth in claim 32, wherein the connection members are electrically connected to copper foil on the insulation layers through via holes, and thus constitute a shielding film enclosing the upper and lower portions of the parts, thereby serving to block a signal interference phenomenon between the parts.

34. The printed circuit board as set forth in claim 33, wherein the connection members and a portion of the shielding film enclosing the upper and lower portions of the parts are connected to a ground circuit.

35. A method of manufacturing a printed circuit board, comprising the steps of:
(a) providing a copper clad laminate in which copper foil is layered on first and second surfaces of a first insulation layer;
(b) forming a plurality of interlayer connection members, which are conductors, by selectively removing the copper foil layered on the first surface of the first insulation layer;
(c) layering a second insulation layer and an RCC, one surface of which is coated with a copper foil, on the first insulation layer;
(d) forming blind via holes in an outermost copper foil and the first insulation layer, and in another outermost copper foil and the second insulation layer; and
(e) forming circuit patterns by patterning the outermost copper foil.

36. The method of manufacturing a printed circuit board as set forth in claim 35, wherein the copper foil layered on the first surface of the first insulation layer is thicker than the copper foil layered on the second surface thereof.

37. The method of manufacturing a printed circuit board as set forth in claim 36, wherein the second insulation layer is thick enough to be capable of filling spaces between the connection members formed by layering the copper foil on the first surface of the first insulation layer.

38. The method of manufacturing a printed circuit board as set forth in claim 35, wherein the step (b) comprises: forming heat radiation layers between the interlayer connection members.

39. The method of manufacturing a printed circuit board as set forth in claim 37, wherein each of the heat radiation layers has an upper surface and a lower surface, widths of which are greater than those of an upper surface and a lower surface of each of the connection members.

40. The method of manufacturing a printed circuit board as set forth in claim 39, further comprising, after the step (d):
forming copper plating layers in the blind via holes to electrically connect the heat radiation layers to the circuit patterns.

41. The method of manufacturing a printed circuit board as set forth in claim 40, wherein each of the connection members and each of the heat radiation layers is thicker than the first insulation layer.

42. The method of manufacturing a printed circuit board as set forth in claim 38, wherein the step (b) further comprises:
forming part mounting regions in regions in which the heat radiation layers are not formed; and
mounting parts in the part mounting regions.

43. The method of manufacturing a printed circuit board as set forth in claim 42, further comprising, after the step (d):
forming copper plating layers in the blind via holes to electrically connect the parts to the circuit patterns.

44. The method of manufacturing a printed circuit board as set forth in claim 43, wherein the parts are any one, or two or more, of a bare IC chip, a passive part, a part having a module packed therein, and a module substrate having various components packed therein.

45. The method of manufacturing a printed circuit board as set forth in claim 44, wherein each of the connection members and each of the heat radiation layers have thicknesses the same as or greater than the parts.

46. The method of manufacturing a printed circuit board as set forth in claim 37, wherein the step (b) further comprises:
forming part mounting regions by selectively removing the copper foil layered on the first surface of the first insulation layer; and
mounting parts in the part mounting regions.

47. The method of manufacturing a printed circuit board as set forth in claim 46, further comprising, after the step (d):
forming copper plating layers in the blind via holes to electrically connect the parts to the circuit patterns.

48. The method of manufacturing a printed circuit board as set forth in claim 47, wherein the parts are any one, or two or more, of a bare IC chip, a passive part, a part having a module packed therein, and a module substrate having various components packed therein.

49. The method of manufacturing a printed circuit board as set forth in claim 48, wherein the connection members have thicknesses the same as or greater than the parts.

50. A method of manufacturing a printed circuit board, comprising the steps of:
(a) providing a copper clad laminate in which copper foil is layered on first and second surfaces of a first insulation layer;
(b) forming a plurality of interlayer connection members, which are conductors, by selectively removing the copper foil layered on the first surface of the first insulation layer;
(c) layering a second insulation layer on the first insulation layer;
(d) layering a third insulation layer and an RCC, one surface of which is coated with copper foil, on the second insulation layer;
(e) forming blind via holes in the first insulation layer and the third insulation layer; and
(f) forming circuit patterns by patterning the outermost copper foil.

51. The method of manufacturing a printed circuit board as set forth in claim 50, wherein the copper foil layered on the first surface of the first insulation layer is thicker than the copper foil layered on the second surface thereof.

52. The method of manufacturing a printed circuit board as set forth in claim 51, wherein the second insulation layer has the same thickness as the copper foil layered on the first surface of the first insulation layer.

53. The method of manufacturing a printed circuit board as set forth in claim 50, wherein the step (b) comprises: forming heat radiation layers between the interlayer connection members.

54. The method of manufacturing a printed circuit board as set forth in claim 53, wherein each of the heat radiation layers has an upper surface and a lower surface, widths of which are greater than those of an upper surface and a lower surface of each of the connection member.

55. The method of manufacturing a printed circuit board as set forth in claim 54, further comprising, after the step (e):
forming copper plating layers in the blind via holes to electrically connect the heat radiation layers to the circuit patterns.

56. The method of manufacturing a printed circuit board as set forth in claim 55, wherein each of the connection members and each of the heat radiation layers have greater thicknesses than the first insulation layer and the third insulation layer.

57. The method of manufacturing a printed circuit board as set forth in claim 54, wherein the step (b) further comprises:
forming part mounting regions in regions in which the heat radiation layers are not formed; and
mounting parts in the part mounting regions.

58. The method of manufacturing a printed circuit board as set forth in claim 57, further comprising, after the step (d):
forming copper plating layers in the blind via holes to electrically connect the parts to the circuit patterns.

59. The method of manufacturing a printed circuit board as set forth in claim 58, wherein the parts are any one, or two or more, of a bare IC chip, a passive part, a part having a module packed therein, and a module substrate having various components packed therein.

60. The method of manufacturing a printed circuit board as set forth in claim 59, wherein each of the connection members and each of the heat radiation layers has a thickness the same as or greater than the parts.

61. The method of manufacturing a printed circuit board as set forth in claim 50, wherein the step (b) further comprises:
forming part mounting regions by selectively removing the copper foil layered on the first surface of the first insulation layer; and
mounting parts in the part mounting regions.

62. The method of manufacturing a printed circuit board as set forth in claim 61, further comprising, after the step (d):
forming copper plating layers in the blind via holes to electrically connect the parts to the circuit patterns.

63. The method of manufacturing a printed circuit board as set forth in claim 62, wherein the parts are any one, or two or more, of a bare IC chip, a passive part, a part having a module packed therein, and a module substrate having various components packed therein.

64. The method of manufacturing a printed circuit board as set forth in claim 63, wherein the connection members have thicknesses the same as or greater than the parts.
